(19) United States
(12) Patent Application Publication
(10) Pub. No.: US 2014/0062610 A1
(43) Pub. Date: Mar. 6, 2014

(54) OSCILLATION CIRCUIT, REAL-TIME CLOCK, AND INFORMATION PROCESSING DEVICE

(71) Applicant: KABUSHIKI KAISHA TOSHIBA, Tokyo (JP)

(72) Inventor: Rui ITO, Kanagawa (JP)

(73) Assignee: KABUSHIKI KAISHA TOSHIBA, Tokyo (JP)

(21) Appl. No.: 13/800,134

(22) Filed: Mar. 13, 2013

(30) Foreign Application Priority Data
Aug. 30, 2012 (JP) 2012-190240

(51) Int. Cl. H03L 5/00

(52) U.S. Cl. CPC H03L 5/00
USPC 331/186

(57) ABSTRACT

According to one embodiment, a switching unit switches between a first state in which the current source is connected to a first capacitance element and a ground electric potential is connected to a second capacitance element and a second state in which a current source is connected to the second capacitance element and the ground electric potential is connected to the first capacitance element. A comparison unit compares a voltage charged in the first capacitance element and a reference voltage with each other in the first state and compares a voltage charged in the second capacitance element and the reference voltage with each other in the second state. A generation unit generates a periodical pulse based on a comparison result acquired by the comparison unit. The switching unit alternately switches between the first state and the second state based on the comparison result acquired by the comparison unit.

### CROSS-REFERENCE TO RELATED APPLICATIONS

This application is based upon and claims the benefit of priority from Japanese Patent Application No. 2012-190240, filed on Aug. 30, 2012; the entire contents of which are incorporated herein by reference.

### FIELD

Embodiments described herein relate generally to an oscillation circuit, a real-time clock, and an information processing device.

### BACKGROUND

In an information processing device such as a personal computer and a mobile terminal, a real-time clock is provided to measure time of the information processing device. The real-time clock operates by being supplied with power from a battery while main power of the information processing device is turned off, thereby measuring a time during which an integrated circuit (IC) of the information processing device does not operate. In other words, the real-time clock is used for measuring a relatively long time while the main power of the information processing device is turned off. Thus, an oscillation circuit used for a real-time clock is preferably a circuit that has low power consumption and a stable frequency of a periodical pulse that is oscillated.

### BRIEF DESCRIPTION OF THE DRAWINGS

FIG. 1 is a diagram illustrating a configuration of an information processing device to which an oscillation circuit according to an embodiment is applied;

FIG. 2 is a diagram illustrating a configuration of the oscillation circuit according to the embodiment;

FIG. 3 is a diagram illustrating the configuration of the oscillation circuit according to the embodiment;

FIG. 4 is a diagram illustrating an operation of the oscillation circuit according to the embodiment;

FIG. 5 is a diagram illustrating advantageous effects of the embodiment;

FIGS. 6A and 6B are diagrams illustrating a configuration and an operation of an oscillation circuit according to a comparative example; and

FIGS. 7A and 7B are diagrams illustrating a configuration and an operation of an oscillation circuit according to another comparative example.

### DETAILED DESCRIPTION

In general, according to one embodiment, there is provided an oscillation circuit including a current source, a first capacitance element, a second capacitance element, a switching unit, a comparison unit, and a generation unit. The switching unit switches between a first state in which the current source is connected to the first capacitance element and a ground electric potential is connected to the second capacitance element and a second state in which the current source is connected to the second capacitance element and the ground electric potential is connected to the first capacitance element. The comparison unit compares a voltage charged in the first capacitance element and a reference voltage with each other in the first state and compares a voltage charged in the second capacitance element and the reference voltage with each other in the second state. The generation unit generates a periodical pulse based on a comparison result acquired by the comparison unit. The switching unit alternately switches between the first state and the second state based on the comparison result acquired by the comparison unit.

Exemplary embodiments of an oscillation circuit, a real-time clock, and an information processing device will be explained below in detail with reference to the accompanying drawings. The present invention is not limited to the following embodiments.

### Embodiment

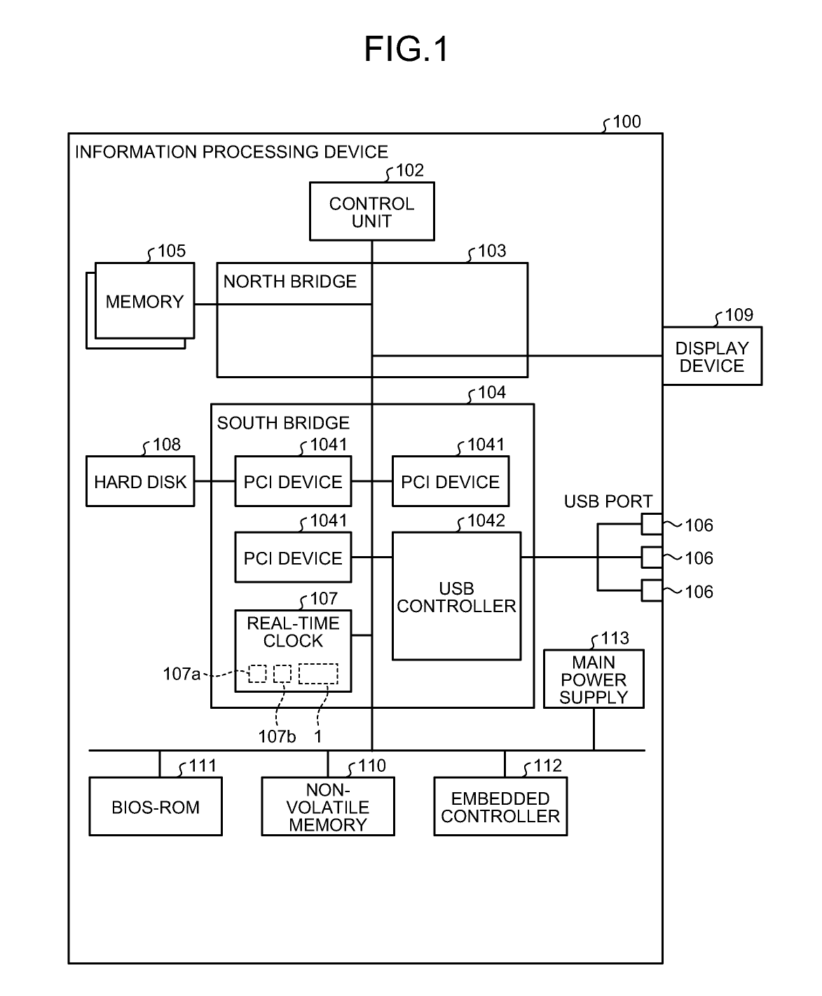

An information processing device 100 to which an oscillation circuit 1 according to an embodiment is applied will be described with reference to FIG. 1. FIG. 1 is a diagram illustrating a configuration of the information processing device 100 to which the oscillation circuit 1 is applied.

In the information processing device 100, a real-time clock 107 including an oscillation circuit 1 is provided to measure time of the information processing device 100. The information processing device 100 measures the time of the information processing device 100 using a clock signal adjusted by the real-time clock 107 in accordance with a periodical pulse generated by the oscillation circuit 1. The information processing device 100, for example, is a personal computer or a mobile terminal. Hereinafter, a case will be exemplarily described in which the information processing device 100 is a personal computer. The description can be similarly applied to a case where the information processing device 100 is a mobile terminal.

Specifically, the information processing device 100 includes a control unit 102, a north bridge 103, a south bridge 104, a memory 105, a USB port 106, a hard disk 108, a display device 109, a non-volatile memory 110, a BIOS ROM 111, an embedded controller 112, and a main power supply 113.

The control unit 102 performs overall control of each unit of the information processing device 100. For example, the control unit 102 loads a system basic input output system (BIOS) stored in the BIOS ROM 111 into the memory 105 and controls various kinds of hardware. In addition, for example, the control unit 102 loads an operating system (OS) stored in the hard disk 108 into the memory 105 and executes the OS, and also executes various kinds of application programs other than the system BIOS and the OS. The control unit 102, for example, is a processor such as a central processing unit (CPU).

The north bridge 103 connects the control unit 102 and the south bridge 104 to each other. The north bridge 103 controls an access to the memory 105 using the control unit 102 and various displays for the display device 109.

The south bridge 104 connects the control unit 102 and various kinds of hardware such as the BIOS ROM 111, the non-volatile memory 110, and the embedded controller 112 to each other.

As illustrated in FIG. 1, the south bridge 104 includes a peripheral components interconnect (PCI) device 1041, a universal serial bus (USB) controller 1042, and a real-time clock 107.

The PCI device 1041 controls input/output of various kinds of data for the hard disk 108.

When a USB device is inserted into the USB port 106, the USB controller 1042 detects a signal indicating the inserting of the USB device into the USB port 106. In addition, the USB controller 1042 controls transmission and reception of various commands and data for the inserted USB device.

The real-time clock 107 has a timer function and, for example, measures a time during which a predetermined integrated circuit (IC) does not operate. For example, when generating a wakeup instruction and supplying the wakeup instruction to each unit, the control unit 102 refers to the real-time clock 107. The wakeup instruction, for example, is used for instructing the BIOS ROM 111 to start up various kinds of hardware disposed inside the information processing device 100, for example, when the time during which an IC as a measurement target does not operate exceeds a predetermined time.

The real-time clock 107 includes an oscillation circuit 1, a battery 107a, and an adjustment circuit 107b. The oscillation circuit 1 generates a periodical pulse by performing an oscillation operation using power supplied from the battery 107a and supplies the generated periodical pulse to the adjustment circuit 107b. The adjustment circuit 107b adjusts the frequency and the like of the periodical pulse, thereby generating a clock signal. The real-time clock 107, for example, performs the above-described timer function using the clock signal. Thus, for example, when the time, during which an IC as a measurement target does not operate, acquired by referring to the real-time clock 107 exceeds a predetermined time, the control unit 102 generates the wakeup instruction and, for example, supplies the wakeup instruction to the BIOS ROM 111.

The memory 105 serves as a work area in which predetermined data is temporarily stored. For example, in the memory 105, the system BIOS stored in the BIOS ROM 111 and the OS and an application program stored in the hard disk 108 are deployed and temporarily stored.

The hard disk 108 stores the OS, various kinds of application programs, and the like.

The display device 109 is a display device such as a liquid crystal display (LCD) for displaying the screen of various application programs, a utility to be described below, or the like under the control of the north bridge 103.

The non-volatile memory 110 stores data in a non-volatile manner. The non-volatile memory 110, for example, is an electrically erasable programmable ROM (EEPROM) or a flash memory.

The main power supply 113 supplies power to each unit by being turned on when a power switch (not illustrated) of the information processing device 100 is turned on, and stops the supply of power to each unit by being turned off when the power switch (not illustrated) of the information processing device 100 is turned off.

In the information processing device 100 illustrated in FIG. 1, the real-time clock 107 operates by being supplied with power from the battery 107a while the main power supply 113 of the information processing device 100 is turned off and, for example, measures a time during which an IC (for example, at least one of the control unit 102, the memory 105, the PCI device 1041, the USB controller 1042, the non-volatile memory 110, the BIOS ROM 111, and the embedded controller 112) of the information processing device 100 does not operate. In other words, the real-time clock 107 operates by being supplied with power from the battery 107a while the main power supply 113 of the information processing device 100 is turned off. Thus, it is preferable that the oscillation circuit 1 used in the real-time clock 107 has low power consumption.

The real-time clock 107 is used for measuring a relatively long time such as a time during which an IC does not operate while the main power supply 113 of the information processing device 100 is turned off. Thus, it is preferable that the frequency of a periodical pulse oscillated by the oscillation circuit 1 used in the real-time clock 107 is stable, for example, to be at about several kHz even when there is an environmental variation (for example, a fluctuation in the voltage of the battery or a fluctuation in the ambient temperature).

Accordingly, it is preferable that the oscillation circuit 1 used in the real-time clock 107 has lower power consumption and has a stable frequency of the oscillated periodical pulse.

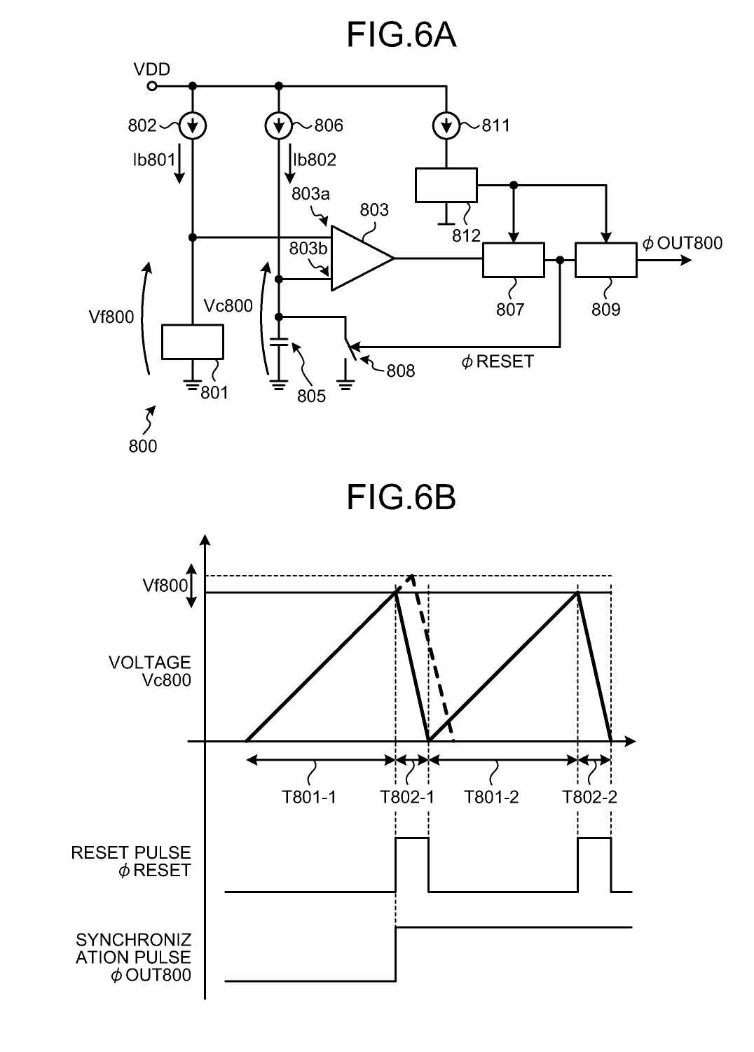

Here, a case will be considered in which the oscillation circuit 800 illustrated in FIG. 6A is used in the real-time clock 107.

To be specific, in the oscillation circuit 800 illustrated in FIG. 6A, a reference voltage generating unit 801 receives a bias current Ib801 generated by a current source 802, generates a reference voltage Vf800, and supplies the generated reference voltage Vf800 to the inverted input terminal 803a of a comparator 803. In addition, the reference capacitance element 805 receives a bias current Ib802 generated by a current source 806, is charged, and supplies a voltage Vc800 corresponding to the electric charge that has been accumulated to the non-inverted input terminal 803b of the comparator 803. In a case where the voltage Vc800 is lower than the reference voltage Vf800, the comparator 803 outputs a signal of a low level to a pulse generator 807 as a result of the comparison, and, in a case where the voltage Vc800 exceeds the reference voltage Vf800, the comparator 803 outputs a signal of a high level to the pulse generator 807 as a result of the comparison.

The pulse generator 807 generates a reset pulse φRESET with a signal of a high level used as a trigger and supplies the generated reset pulse to a discharge switch 808 and a frequency demultiplier 809. The discharge switch 808 is turned on in accordance with the reset pulse φRESET, thereby discharging electric charge accumulated in the reference capacitance element 805 to the ground electric potential. In addition, the frequency demultiplier 809 frequency-divides the reset pulse φRESET and outputs a resultant pulse as a periodical pulse φOUT800. In the oscillation circuit 800, in order to adjust a power source voltage supplied to the pulse generator 807 and the frequency demultiplier 809, a current source 811 and a power source adjusting circuit 812 are arranged.

In the oscillation circuit 800 illustrated in FIG. 6A, as illustrated in FIG. 6B, in period T801, the reference capacitance element 805 is linearly charged by being supplied with a bias current Ib802 by the current source 806 in the state in which the discharge switch 808 is turned off, and when the voltage Vc800 of the reference capacitance element 805 arrives at the reference voltage Vf800, in period T802, the discharge switch 808 is turned on, whereby the electric charge of the reference capacitance element 805 is rapidly discharged. By repeating this process, a reset pulse φRESET is generated, whereby a periodical pulse φOUT800 is generated. In such a case, although the length of period T802 for discharging the reference capacitance element 805 is set to a length that is determined in advance, in a case where the characteristics of the reference capacitance element 805 vary for each oscillation circuit 800, for example, there is a possibility that the discharge switch 808 cannot completely discharge the electric charge of the reference capacitance element 805 within period T802-1. In a case where the reference capacitance element 805 cannot be completely discharged, when the reference capacitance element 805 is charged in the next period T801-2, there is a possibility that a length until the voltage of the reference capacitance element 805 arrives at the reference voltage Vf800, that is, period T801-2 is shorter than period T801-1. From this, there is a possibility that the frequency of the oscillated periodical pulse varies to be unstable, and accordingly, it tends to be difficult for the real-time clock 107 to accurately measure the time during which the IC does not operate.

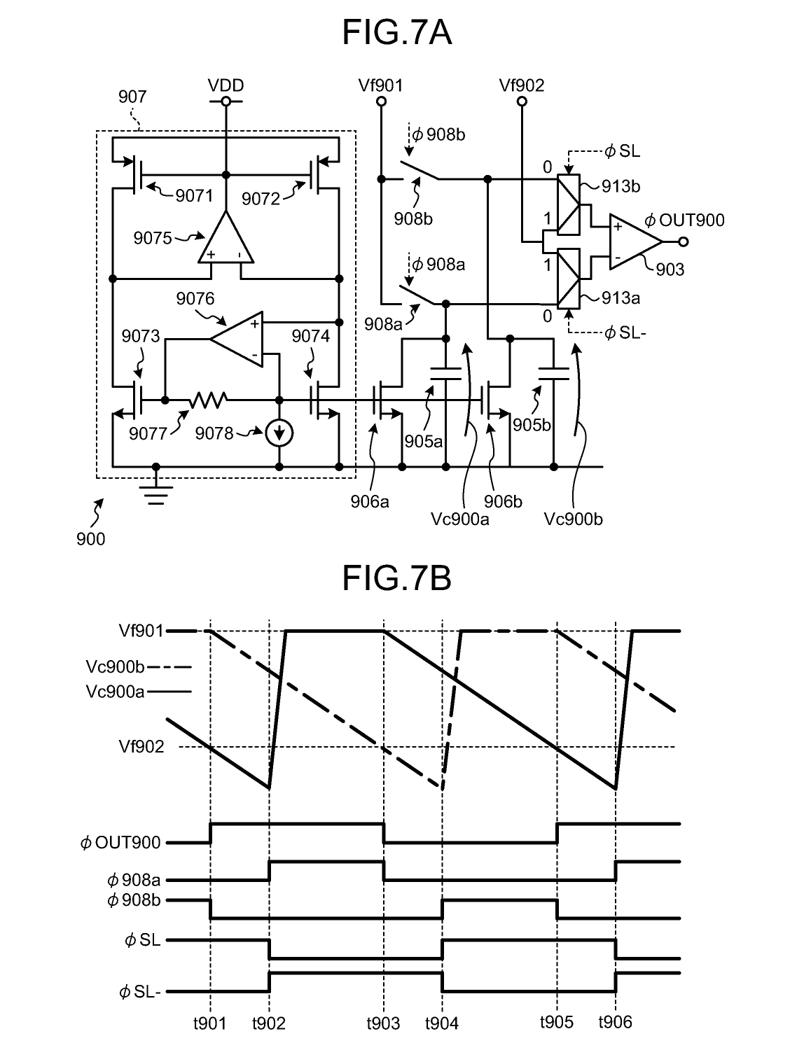

Alternatively, a case will be considered in which the oscillation circuit 900 illustrated in FIG. 7A is used in the real-time clock 107.

More specifically, in the oscillation circuit 900 illustrated in FIG. 7A, a reference current adjusting unit 907 supplies a bias for generating the reference current to transistors 906a and 906b. The transistors 906a and 906b operate as a current source that allows a reference current according to the bias. The reference current adjusting unit 907 has transistors 9071 to 9074, differential amplifiers 9075 and 9076, and a resistor 9077. The transistor 9074 and two transistors 906a and 906b configure a current mirror circuit and mirrors the drain current of the transistor 9074 to the two transistors 906a and 906b.

In addition, reference voltages Vf901 and Vf902, which are mutually different levels, are supplied to the oscillation circuit 900 from the outside. Two sets of circuits in which switches 908a and 908b and reference capacitance elements 905a and 905b are connected in series are connected in parallel to the reference voltage Vf901. Two reference capacitance elements 905a and 905b are connected to a comparator 903 through two selectors 913a and 913b. In addition, the reference voltage Vf902 is connected to two selectors 913a and 913b.

In the oscillation circuit 900 illustrated in FIG. 7A, as illustrated in FIG. 7B, two switches 908a and 908b are alternately turned on in accordance with two control signals φ908a and φ908b being alternately in the active level, whereby the two reference capacitance elements 905a and 905b are alternately charged. Then, when the control signal φSL is in the active level, the comparator 903 compares a voltage Vc900a and the reference voltage Vf902 with each other, and, a signal of the low level is output as a periodical pulse φOUT900 as a result of the comparison in a case where the voltage Vc900a is higher than the reference voltage Vf902, and a signal of the high level is output as a periodical pulse φOUT900 as a result of the comparison in a case where the voltage Vc900a is below the reference voltage Vf902. In addition, when the control signal φSL⁻ is in the active level, the comparator 903 compares the voltage Vc900b and the reference voltage Vf902 with each other, a signal of the low level is output as the periodical pulse φOUT900 as a result of the comparison in a case where the voltage Vc900b is lower than the reference voltage Vf902, and a signal of the high level is output as the periodical pulse φOUT900 as a result of the comparison in a case where the voltage Vc900b exceeds the reference voltage Vf902.

At this time, for example, when the control signal φ908a becomes an active level at timing t902, the reference capacitance element 905a is rapidly charged and maintains a reference voltage Vf901, and, when the control signal φ908a becomes a non-active level at timing t903, the reference capacitance element 905a is slowly discharged in a linear manner by the transistor 906a until timing t906. For example, when the control signal φ908b becomes the non-active level at timing t901, the reference capacitance element 905b is slowly discharged in a linear manner by the transistor 906b until timing t904, and, when the control signal φ908b becomes the active level at timing t904, the reference capacitance element 905b is rapidly charged and maintains the reference voltage Vf901.

In other words, the discharge periods of the two reference capacitance elements 905a and 905b partially overlap with each other, and, during a period in which one of the two reference capacitance elements 905a and 905b is discharged, the other is rapidly charged. In this case, since two current sources (the transistors 906a and 906b) allow currents to flow constantly, the power consumption of the oscillation circuit 900 may easily increase. In addition, since the driving capability of an external current source used for supplying the reference voltage Vf901 is much greater than that of the transistors 906a and 906b, and the external current source is regarded to supply an extremely large current to the oscillation circuit 900, the power consumption of the oscillation circuit 900 easily increases from this point of view as well. From this, since there is a possibility that the source power of the battery 107a is depleted, it tends to be difficult for the real-time clock 107 to measure a time during which the IC does not operate.

Thus, in this embodiment, in order to reduce the power consumption of the oscillation circuit 1 and stabilize the frequency of the periodical pulse to be oscillated, the following plans are devised.

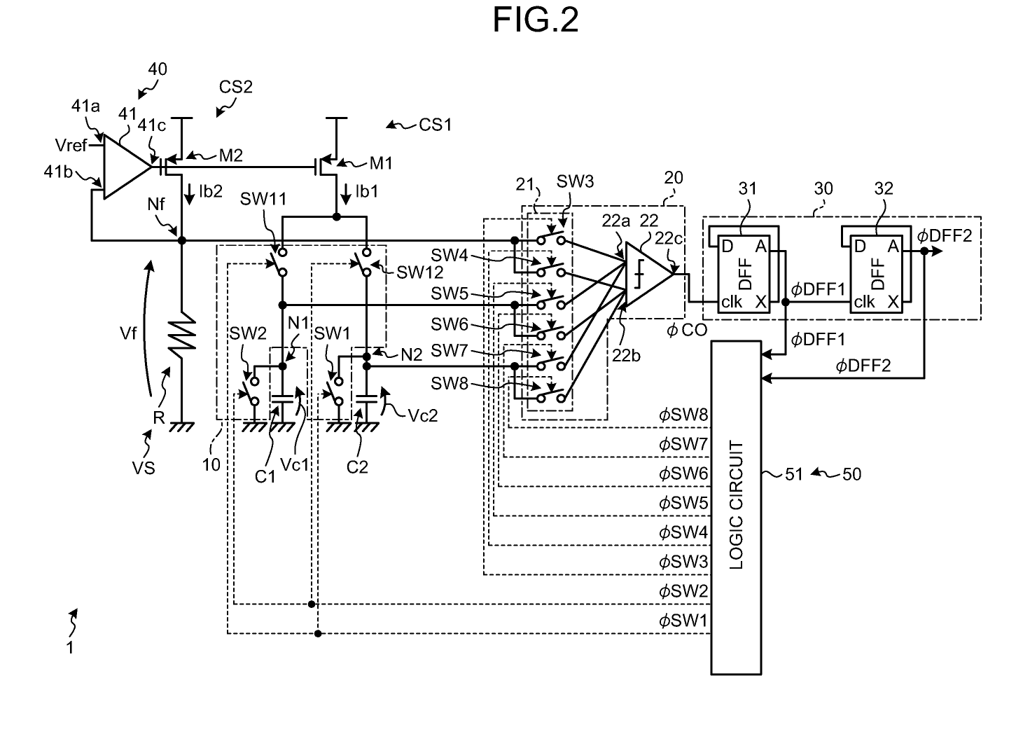

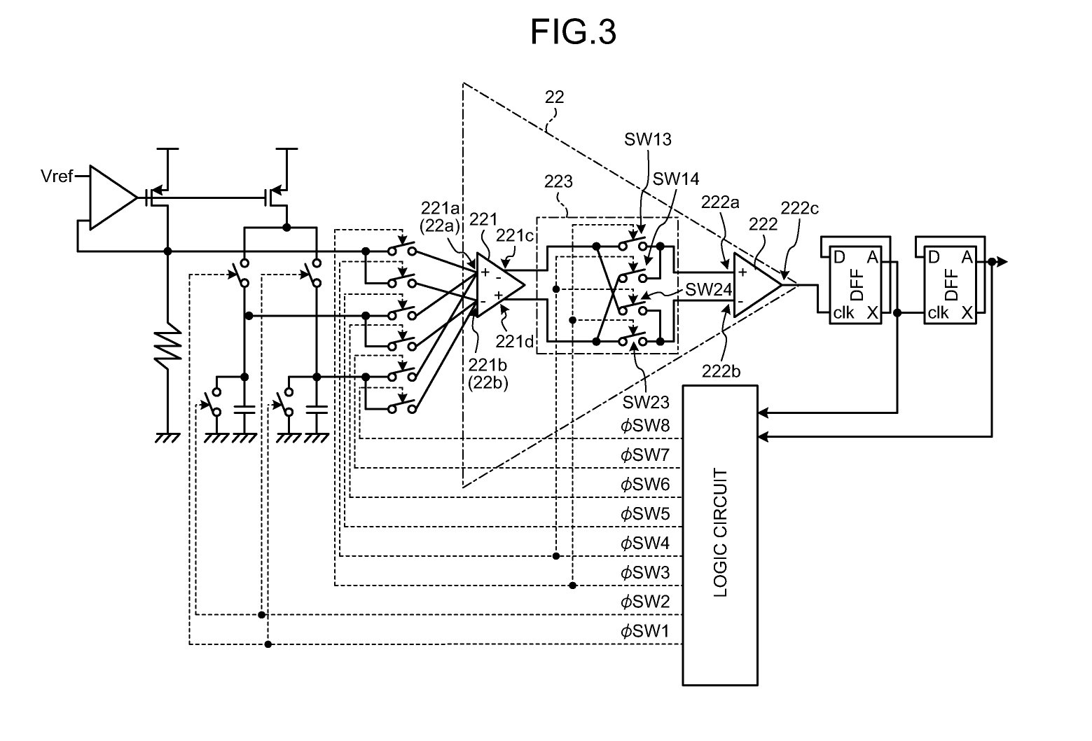

More specifically, as illustrated in FIGS. 2 and 3, the oscillation circuit 1 includes current sources CS1 and CS2, a voltage source VS, capacitance elements C1 and C2, a switching unit 10, a differential amplification unit 40, a comparison unit 20, a generation unit 30, and a control unit 50. FIGS. 2 and 3 are diagrams that illustrate the configuration of the oscillation circuit 1.

The current source CS1 receives a bias voltage from the differential amplification unit 40 and generates a bias current Ib1 in accordance with the bias voltage. The current source CS1, for example, includes a transistor M1 and generates a drain current of the transistor M1 as the bias current Ib1 in accordance with the bias voltage applied to the gate of the transistor M1. The current source CS1 allows the generated bias current Ib1 to flow to the switching unit 10.

The current source (second current source) CS2 receives a bias voltage from the differential amplification unit 40 and generates a bias current Ib2 in accordance with the bias voltage. The current source CS2, for example, includes a transistor M2 and generates a drain current of the transistor M2 as the bias current Ib2 in accordance with the bias voltage applied to the gate of the transistor M2. The current source CS2 allows the generated bias current Ib2 to flow through a reference node Nf. The current source CS2 configures a current mirror circuit of the current source CS1 through the differential amplification unit 40.

For example, by configuring the dimensions (gate width/gate length) of the transistors M1 and M2 to be equivalent to each other, the bias currents Ib1 and Ib2 may be adjusted to be equivalent to each other.

The voltage source VS is connected to the current source CS2 through the reference node Nf. The voltage source VS receives a current flowing through the reference node Nf in accordance with the current source CS2 and generates a voltage Vf according to the current. The voltage source VS, for example, includes a resistance element and generates a voltage Vf according to the current using a resistance element. The voltage Vf generated by the voltage source VS is supplied to the differential amplification unit 40 and the comparison unit 20 as the voltage Vf of the reference node Nf.

The capacitance element (first capacitance element) C1 is connected to the current source CS1 through the switching unit 10. For example, one end of the capacitance element C1 is connected to the current source CS1 through the switching unit 10 and is connected to the comparison unit 20. The other end of the capacitance element C1 is connected to the ground electric potential. The capacitance element C1 is connected in parallel with the capacitance element C2 with respect to the switching unit 10.

The capacitance element (second capacitance element) C2 is connected to the current source CS1 through the switching unit 10. For example, one end of the capacitance element C2 is connected to the current source CS1 through the switching unit 10 and is connected to the comparison unit 20. The other end of the capacitance element C2 is connected to the ground electric potential. The capacitance element C2 is connected in parallel with the capacitance element C1 with respect to the switching unit 10.

The switching unit 10 switches between a first state and a second state. The first state is a state in which both the other end of the capacitance element C1 and the other end of the capacitance element C2 are connected to the ground electric potential, the current source CS1 is connected to one end of the capacitance element C1, and the ground electric potential is connected to one end of the capacitance element C2. In other words, the first state is a state in which the capacitance element C1 is chargeable, and the capacitance element C2 is dischargeable. The second state is a state in which both the other end of the capacitance element C1 and the other end of the capacitance element C2 are connected to the ground electric potential, the current source CS1 is connected to one end of the capacitance element C2, and the ground electric potential is connected to one end of the capacitance element C1. In other words, the second state is a state in which the capacitance element C2 is chargeable, and the capacitance element C1 is dischargeable.

For example, the switching unit 10 includes switches SW1, SW2, SW11, and SW12. The switch SW1 has one end connected to the ground electric potential and the other end connected to one end of the capacitance element C2 through a node N2. In other words, the switch SW1 is configured so as to connect one end of the capacitance element C2 to the ground electric potential. The switch SW2 has one end connected to the ground electric potential and the other end connected to one end of the capacitance element C1 through a node N1. In other words, the switch SW2 is configured so as to connect one end of the capacitance element C1 to the ground electric potential. The switch SW11 has one end connected to the current source CS1 and the other end connected to one end of the switch SW2 and one end of the capacitance element C1 through the node N1. In other words, the switch SW11 is configured so as to connect one end of the capacitance element C1 to the current source CS1. The switch SW12 has one end connected to the current source CS1 and the other end connected to one end of the switch SW1 and one end of the capacitance element C2 through the node N2. In other words, the switch SW12 is configured so as to connect one end of the capacitance element C2 to the current source CS1.

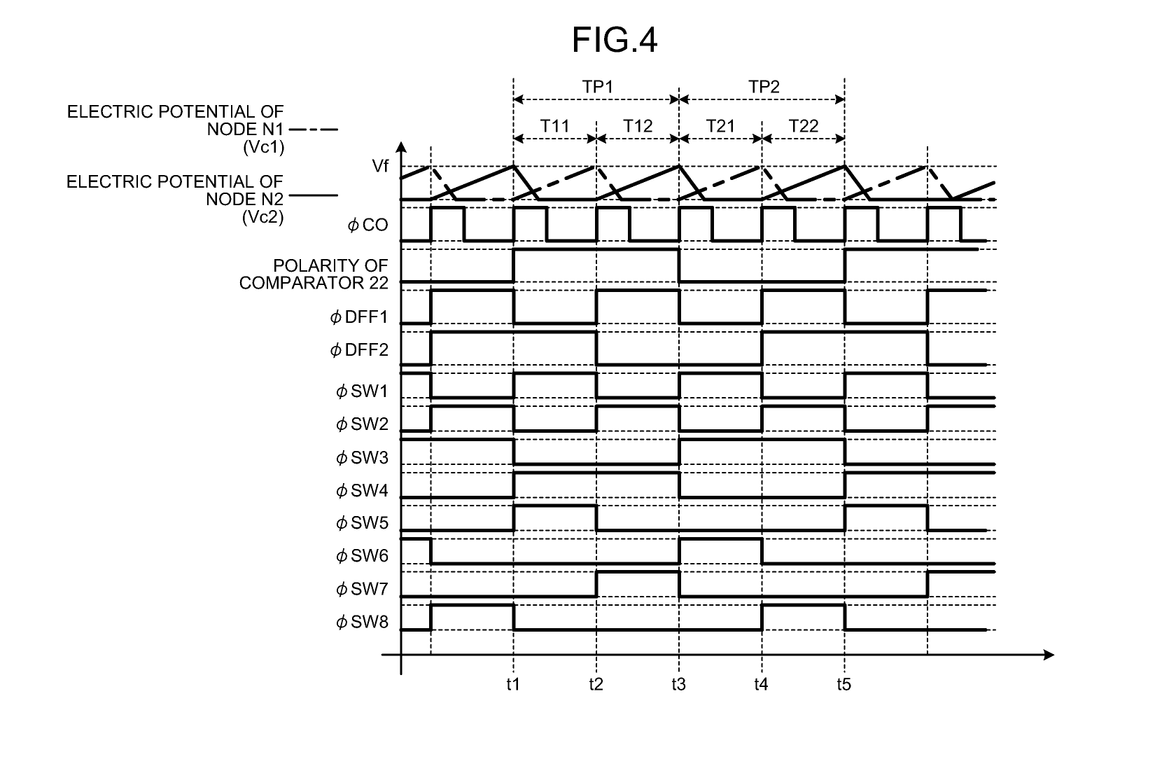

The switches SW1 and SW11 receive a control signal φSW1 together and are turned on and off in synchronization with each other in accordance with the control signal φSW1. The switches SW2 and SW12 receive a control signal φSW2 together and are turned on and off in synchronization with each other in accordance with the control signal φSW2. Since the control signals φSW1 and φSW2 are mutually exclusive signals, in other words, signals of which one is acquired by logically inverting the other (see FIG. 4), a set of the switches SW1 and SW11 and a set of the switches SW2 and SW12 are turned on and off in a mutually-exclusively manner. From this, the switching unit 10 switches between the first state and the second state in accordance with the control signals φSW1 and φSW2. In other words, the switching unit 10 allows the oscillation circuit 1 to perform the operation of the first state and the operation of the second state in a time divisional manner.

The differential amplification unit 40 receives a standard reference voltage Vref from the outside thereof and receives the voltage Vf of the reference node Nf from the reference node Nf. For example, the differential amplification unit 40 includes an operational amplifier 41. An input terminal (for example, the non-inverted input terminal) 41a of the operational amplifier 41 receives the standard reference voltage Vref, and an input terminal (for example, the inverted input terminal) 41b of the operational amplifier 41 is connected to the reference node Nf. The output terminal 41c of the operational amplifier 41 is connected to the gate of the transistor M1 of the current source CS1 and the gate of the transistor M2 of the current source CS2.

From this, the differential amplification unit 40 performs differential amplification of the standard reference voltage Vref and the voltage Vf and supplies a bias voltage as a result of the differential amplification to both the current sources CS1 and CS2. In other words, the differential amplification unit 40 adjusts the bias voltage of the current source CS2 such that the voltage Vf of the reference node Nf becomes the standard reference voltage Vref and supplies the adjusted bias voltage simultaneously to both the current sources CS1 and CS2. Since the differential amplification unit 40 performs compensation such that the drain electric potential of the transistor M2 becomes the standard reference voltage Vref, it can be regarded that the current source CS2 configures an electric-potential-type current mirror circuit of the current source CS1 through the differential amplification unit 40.

The comparison unit 20 receives the voltage Vf of the reference node Nf as a reference voltage. In the first state, that is, the state in which the capacitance element C1 is chargeable, and the capacitance element C2 is dischargeable, the comparison unit 20 compares the voltage Vc1 charged in the capacitance element C1 and the reference voltage Vf with each other. In addition, in the second state, that is, the state in which the capacitance element C2 is chargeable, and the capacitance element C1 is dischargeable, the comparison unit 20 compares the voltage Vc2 charged in the capacitance element C2 and the reference voltage Vf with each other. The comparison unit 20 supplies a comparison result φCO to the generation unit 30.

The comparison unit 20 switches a comparison operation between a first comparison operation and a second comparison operation for every predetermined period (for example, for every periods TP1 and TP2 (see FIG. 4) including periods T11 and T21 in which the state is switched to the first state and periods T12 and T22 in which the state is switched to the second state). For example, the comparison unit 20 includes a connection unit 21 and a comparator 22. The comparator 22 includes an input terminal (for example, a non-inverted input terminal) 22a, an input terminal (for example, an inverted input terminal) 22b, and an output terminal 22c. The comparison unit 20, for example, for every periods TP1 and TP2 (see FIG. 4) including the periods T11 and T21 in which the state is switched to the first state and the periods T12 and T22 in which the state is switched to the second state, inverts the polarity of the inside of the comparator 22 to the first polarity or the second polarity. For example, the comparison unit 20 inverts the polarity of the inside of the comparator 22 in accordance with control signals φSW3 and φSW4.

In accordance with this, for example, in the first polarity and the first state, the connection unit 21 connects the capacitance element C1 to the input terminal (first input terminal) 22a and connects the reference node Nf to the input terminal 22b (second input terminal), thereby electrically cutting off the capacitance element C2 from the comparator 22. In the first polarity and the second state, the connection unit 21 connects the capacitance element C2 to the input terminal 22a and connects the reference node Nf to the input terminal 22b, thereby electrically cutting off the capacitance element C1 from the comparator 22. In the second polarity and the first state, the connection unit 21 connects the capacitance element C1 to the input terminal 22b and connects the reference node Nf to the input terminal 22a, thereby electrically cutting off the capacitance element C2 from the comparator 22. In the second polarity and the second state, the connection unit 21 connects the capacitance element C2 to the input terminal 22b and connects the reference node Nf to the input terminal 22a, thereby electrically cutting off the capacitance element C1 from the comparator 22.

More specifically, the connection unit 21 includes a plurality of switches SW3 to SW8. The switch SW3 has one end connected to the reference node Nf and the other end connected to the input terminal 22a of the comparator 22. In other words, the switch SW3 is configured so as to connect the reference node Nf to the input terminal 22a of the comparator 22. The switch SW4 has one end connected to the reference node Nf and the other end connected to the input terminal 22b of the comparator 22. In other words, the switch SW4 is configured so as to connect the reference node Nf to the input terminal 22b of the comparator 22. The switch SW5 has one end connected to a node N1 and the other end connected to the input terminal 22a of the comparator 22. In other words, the switch SW5 is configured so as to connect one end of the capacitance element C1 to the input terminal 22a of the comparator 22. The switch SW6 has one end connected to the node N1 and the other end connected to the input terminal 22b of the comparator 22. In other words, the switch SW6 is configured so as to connect one end of the capacitance element C1 to the input terminal 22b of the comparator 22. The switch SW7 has one end connected to a node N2 and the other end connected to the input terminal 22a of the comparator 22. In other words, the switch SW7 is configured so as to connect one end of the capacitance element C2 to the input terminal 22a of the comparator 22. The switch SW8 has one end connected to the node N2 and the other end connected to the input terminal 22b of the comparator 22. In other words, the switch SW8 is configured so as to connect one end of the capacitance element C2 to the input terminal 22b of the comparator 22.

At this time, for example, in the first polarity and the first state, the connection unit 21 turns on the switches SW4 and SW5 and turns off the switches SW3 and SW6 to SW8. In the first polarity and the second state, the connection unit 21 turns on the switches SW4 and SW7 and turns off the switches SW3, SW5, SW6, and SW8. In the second polarity and the first state, the connection unit 21 turns on the switches SW3 and SW6 and turns off the switches SW4, SW5, SW7, and SW8. In the second polarity and the second state, the connection unit 21 turns on the switches SW3 and SW8 and turns off the switches SW4 to SW7.

In addition, for example, in the first polarity, the comparator 22 outputs a signal of the low level as a comparison result φCO in a case where the level of the signal of the input terminal 22b (second input terminal) is lower than the level of the signal of the input terminal (first input terminal) 22a and outputs a signal of the high level as a comparison result φCO in a case where the level of the signal of the input terminal 22b (second input terminal) is lower than the level of the signal of the input terminal (first input terminal) 22a. For example, in the second polarity, the comparator 22 outputs a signal of the lower level as a comparison result φCO in a case where the level of the signal of the input terminal (first input terminal) 22a is lower than the level of the signal of the input terminal 22b (second input terminal) and outputs a signal of the high level as a comparison result φCO in a case where the level of the signal of the input terminal 22b (second input terminal) is lower than the level of the signal of the input terminal (first input terminal) 22a.

For example, the comparator 22, as illustrated in FIG. 3, includes a differential amplifier 221, a comparator 222, and a connection circuit 223. The differential amplifier 221 has an input terminal (for example, a non-inverted input terminal) 221a, an input terminal (for example, an inverted input terminal) 221b, an output terminal (for example, an inverted output terminal) 221c, and an output terminal (for example, a non-inverted output terminal) 221d. The differential amplifier 221 performs differential amplification of signals received from the input terminals 221a and 221b (the first input terminal and the second input terminal) and outputs one pair of differential signals from the output terminals 221c and 221d as a result of the differential amplification. The comparator 222 has an input terminal (for example, a non-inverted input terminal) 222a, an input terminal (for example, an inverted input terminal) 222b, and an output terminal 222c. The comparator 222 receives one pair of differential signals from one pair of the input terminals 222a and 222b through the connection circuit 223, compares the one pair of differential signals, and outputs a comparison result φCO from the output terminal 222c. The connection circuit 223 connects the differential amplifier 221 and the comparator 222 to each other. In addition, the connection circuit 223 changes the connection configuration of the differential amplifier 221 and the comparator 222 so as to invert the polarity of the inside of the comparator 22 in accordance with the control signals φSW3 and φSW4.

For example, in the first polarity, the connection circuit 223 connects the output terminal 221c (first output terminal) to the input terminal 222b (fourth input terminal) and connects the output terminal 221d (second output terminal) to the input terminal 222a (third input terminal). In the second polarity, the connection circuit 223 connects the output terminal 221c to the input terminal 222a and connects the output terminal 221d to the input terminal 222b.

More specifically, the connection circuit 223 includes a plurality of switches SW13, SW23, SW14, and SW24. The switch SW13 has one end connected to the output terminal 221c of the differential amplifier 221 and the other end connected to the input terminal 222a of the comparator 222. The switch SW23 has one end connected to the output terminal 221d of the differential amplifier 221 and the other end connected to the input terminal 222b of the comparator 222. The switch SW14 has one end connected to the output terminal 221d of the differential amplifier 221 and the other end connected to the input terminal 222a of the comparator 222. The switch SW24 has one end connected to the output terminal 221c of the differential amplifier 221 and the other end connected to the input terminal 222b of the comparator 222.

At this time, for example, in the first polarity, the connection circuit 223 turns on the switches SW13 and SW23 and turns off the switches SW14 and SW24. In the second polarity, the connection circuit 223 turns on the switches SW14 and SW24 and turns off the switches SW13 and SW23.

The generation unit 30 illustrated in FIG. 2 receives the comparison result φCO from the comparison unit 20. The generation unit 30 generates a periodical pulse φDFF2 based on the comparison result φCO acquired by the comparison unit 20. For example, the generation unit 30 includes D flip-flops 31 and 32. The D flip-flop 31 has a clock terminal clk connected to the output terminal 22c of the comparator 22, a data input terminal D connected to an inverted output terminal X, and a non-inverted output terminal A connected to the control unit 50 and the D flip-flop 32. The D flip-flop 32 has a clock terminal clk connected to the non-inverted output terminal A of the D flip-flop 31, a data input terminal D connected to the inverted output terminal X, and a non-inverted output terminal A connected to the control unit 50 and the outside thereof (for example, the adjustment circuit 107b illustrated in FIG. 1). From this, the generation unit 30 outputs the generated periodical pulse φDFF2 to the outside thereof (for example, the adjustment circuit 107b illustrated in FIG. 1).

For example, the D flip-flop 31 maintains data appearing in the inverted output terminal X of the D flip-flop 31 in synchronization with the comparison result φCO (for example, in synchronization with a rise in the waveform of the comparison result φCO). In addition, the D flip-flop 31 outputs the maintained data from the non-inverted output terminal A to the control unit 50 and the D flip-flop 32 as a periodical pulse φDFF1. For example, the D flip-flop 32 maintains data appearing in the inverted output terminal X of the D flip-flop 32 in synchronization with the periodical pulse φDFF1 (for example, in synchronization with a rise in the waveform of the periodical pulse φDFF1). In addition, the D flip-flop 32 outputs the maintained data from the non-inverted output terminal A to the control unit 50 and the outside thereof (for example, the adjustment circuit 107b illustrated in FIG. 1) as a periodical pulse φDFF2.

The control unit 50 receives the periodical pulses φDFF1 and φDFF2 from the generation unit 30. The control unit 50 controls the switching unit 10 and the comparison unit 20 in accordance with the periodical pulses φDFF1 and φDFF2. For example, the control unit 50 generates control signals φSW1 to φSW8 (see FIG. 4) based on the periodical pulses φDFF1 and φDFF2, supplies control signals φSW1 and φSW2 to the switching unit 10, and supplies control signals φSW3 to φSW8 to the comparison unit 20. For example, the control unit 50 includes a logic circuit 51. The logic circuit 51, for example, includes a predetermined gate logic (not illustrated in the figure), performs a predetermined logical operation for the periodical pulses φDFF1 and φDFF2 using the predetermined gate logic, thereby generating control signals φSW1 to φSW8.

Next, the operation of the oscillation circuit 1 will be described with reference to FIG. 4. FIG. 4 is a diagram that illustrates the operation of the oscillation circuit 1.

In the oscillation circuit 1, the switching unit 10 switches the state to the first state in period T11, the switching unit 10 switches the state to the second state in period T12, the switching unit 10 switches the state to the first state in period T21, and the switching unit 10 switches the state to the second state in period T22. In other words, the switching unit 10 alternately switches between the first state and the second state. In addition, in the oscillation circuit 1, the comparison unit 20 sets the polarity of the inside of the comparator 22 to first polarity in period TP1 including periods T11 and T12, and the comparison unit 20 sets the polarity of the inside of the comparator 22 to second polarity in period TP1 including periods T21 and T22. In other words, the comparison unit 20 alternately inverts the polarity of the inside of the comparator 22 between the first polarity and the second polarity.

More specifically, at timing t1, the control signal φSW1 is set to be in the active level, and the control signal φSW2 is set to be in the non-active level. From this, the switching unit 10 switches the state to the first state, that is, the state in which the capacitance element C1 is chargeable, and the capacitance element C2 is dischargeable. In addition, the control signal φSW3 is set to be in the non-active level, and the control signal φSW4 is set to be in the active level. From this, the comparison unit 20 sets the polarity of the inside of the comparator 22 to the first polarity.

In addition, the control signals φSW4 and φSW5 are set to be in the active level, and the control signals φSW3 and φSW6 to φSW8 are set to be in the non-active level, whereby the switches SW4 and SW5 are turned on, and the switches SW3 and SW6 to SW8 are turned off. From this, the capacitance element C1 is connected to the input terminal (first input terminal) 22a, and the reference node Nf is connected to the input terminal 22b (second input terminal), whereby the capacitance element C2 is electrically cut off from the comparator 22.

While the capacitance element C2 is discharged in accordance with this, the capacitance element C1 is slowly charged in a linear manner by the current source CS1, and the comparison unit 20 compares the voltage Vc1 charged in the capacitance element C1 and the reference voltage Vf with each other and outputs a comparison result φCO. For example, while the comparison unit 20 outputs a comparison result φCO of the high level corresponding to the comparison result of the previous period right after timing t1, a comparison result φCO of the low level is output at the subsequent timing due to the voltage Vc1 that is lower than the reference voltage Vf (≈standard reference voltage Vref), and then a comparison result φCO of the high level is output due to the voltage Vc1 at timing t2 that exceeds the reference voltage Vf. In accordance with this, the generation unit 30 transits the levels of the periodical pulses φDFF1 and φDFF2.

At timing t2, in accordance with the transitions of the levels of the periodical pulses φDFF1 and DFF2, the control signal φSW1 is set to be in the non-active level, and the control signal φSW2 is set to be in the active level. From this, the switching unit 10 switches the state to the second state, that is, the state in which the capacitance element C2 is chargeable, and the capacitance element C1 is dischargeable. At this time, the control signal φSW3 is set to be in the non-active level, and the control signal φSW4 is set to be in the active level. From this, the comparison unit 20 maintains the polarity of the inside of the comparator 22 at the first polarity.

In addition, the control signals φSW4 and φSW7 are set to be in the active level, and the control signals φSW3, φSW5, φSW6, and φSW8 are set to be in the non-active level, whereby the switches SW4 and SW7 are turned on, and the switches SW3, SW5, SW6, and SW8 are turned off. From this, the capacitance element C1 is connected to the input terminal (first input terminal) 22a, and the reference node Nf is connected to the input terminal 22b (second input terminal), whereby the capacitance element C2 is electrically cut off from the comparator 22.

While the capacitance element C1 is discharged in accordance with this, the capacitance element C2 is slowly charged in a linear manner by the current source CS1, and the comparison unit 20 compares the voltage Vc2 charged in the capacitance element C2 and the reference voltage Vf with each other and outputs a comparison result φCO. For example, while the comparison unit 20 outputs a comparison result φCO of the high level corresponding to the comparison result of the previous period right after timing t2, a comparison result φCO of the low level is output at the subsequent timing due to the voltage Vc2 that is lower than the reference voltage Vf (≈standard reference voltage Vref), and then a comparison result φCO of the high level is output due to the voltage Vc2 at timing t3 that exceeds the reference voltage Vf. In accordance with this, the generation unit 30 transits the level of the periodical pulse φDFF1 and maintains the level of the periodical pulse φDFF2.

At timing t3, in accordance with the transition of the level of the periodical pulse φDFF1 and the maintaining of the level of the periodical pulse φDFF2, the control signal φSW1 is set to be in the active level, and the control signal φSW2 is set to be in the non-active level. From this, the switching unit 10 switches the state to the first state, that is, the state in which the capacitance element C1 is chargeable, and the capacitance element C2 is dischargeable. In addition, the control signal φSW3 is set to be in the active level, and the control signal φSW4 is set to be in the non-active level. From this, the comparison unit 20 inverts the polarity of the inside of the comparator 22 to the second polarity.

In addition, the control signals φSW3 and φSW6 are set to be in the active level, and the control signals φSW4, φSW5, φSW7, and φSW8 are set to be in the non-active level, whereby the switches SW3 and SW6 are turned on, and the switches SW4, SW5, SW7, and SW8 are turned off. From this, the capacitance element C1 is connected to the input terminal 22b, and the reference node Nf is connected to the input terminal 22a, whereby the capacitance element C2 is electrically cut off from the comparator 22.

While the capacitance element C2 is discharged in accordance with this, the capacitance element C1 is slowly charged in a linear manner by the current source CS1, and the comparison unit 20 compares the voltage Vc1 charged in the capacitance element C1 and the reference voltage Vf with each other and outputs a comparison result φCO. For example, while the comparison unit 20 outputs a comparison result φCO of the high level corresponding to the comparison result of the previous period right after timing t3, a comparison result φCO of the low level is output at the subsequent timing due to the voltage Vc1 that is lower than the reference voltage Vf (≈standard reference voltage Vref), and then a comparison result φCO of the high level is output due to the voltage Vc1 at timing t4 that exceeds the reference voltage Vf. In accordance with this, the generation unit 30 transits the levels of the periodical pulses φDFF1 and φDFF2.

At timing t4, in accordance with the transitions of the levels of the periodical pulses φDFF1 and φDFF2, the control signal φSW1 is set to be in the non-active level, and the control signal φSW2 is set to be in the active level. From this, the switching unit 10 switches the state to the second state, that is, the state in which the capacitance element C2 is chargeable, and the capacitance element C1 is dischargeable. At this time, the control signal φSW3 is set to be in the active level, and the control signal φSW4 is set to be in the non-active level. From this, the comparison unit 20 maintains the polarity of the inside of the comparator 22 at the second polarity.

In addition, the control signals φSW3 and φSW8 are set to be in the active level, and the control signals φSW4 to φSW7 are set to be in the non-active level, whereby the switches SW3 and SW8 are turned on, and the switches SW4 to SW7 are turned off. From this, the capacitance element C2 is connected to the input terminal 22b, and the reference node Nf is connected to the input terminal 22a, whereby the capacitance element C1 is electrically cut off from the comparator 22.

While the capacitance element C1 is discharged in accordance with this, the capacitance element C2 is slowly charged in a linear manner by the current source CS1, and the comparison unit 20 compares the voltage Vc2 charged in the capacitance element C2 and the reference voltage Vf with each other and outputs a comparison result φCO. For example, while the comparison unit 20 outputs a comparison result φCO of the high level corresponding to the comparison result of the previous period right after timing t4, a comparison result φCO of the low level is output at the subsequent timing due to the voltage Vc2 that is lower than the reference voltage Vf (≈standard reference voltage Vref), and then a comparison result φCO of the high level is output due to the voltage Vc2 at timing t5 that exceeds the reference voltage Vf. In accordance with the comparison result φCO, the generation unit 30 generates and outputs the periodical pulses φDFF1 and φDFF2.

At timing t5, the same operation as that performed at timing t1 is performed. In other words, after timing t5, the same operations as those performed at timing t1 to timing t5 are repeatedly performed.

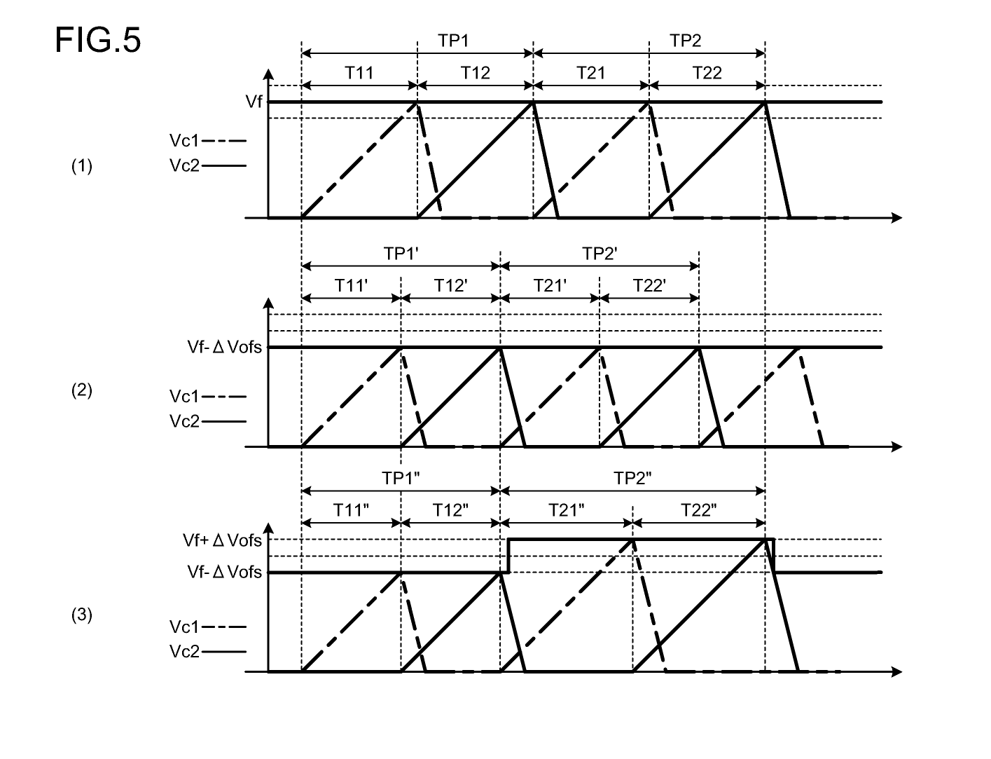

Next, advantages according to the inversion of the polarity of the comparator 22 using the comparison unit 20 will be described with reference to FIG. 5. FIG. 5 is a waveform diagram that illustrates the advantages of inverting the polarity of the comparator 22 using the comparison unit 20.

As described above, the comparison unit 20 compares the voltage Vc1 (or the voltage Vc2) and the reference voltage Vf with each other.

Here, suppose a case (ideal case) in which the comparator 22 of the comparison unit 20 does not have an offset. In such a case, as illustrated in FIG. 5 (1), switching from the period T11 of the first state to the period T12 of the second state can be performed by setting the comparison result φCO to the high level at timing when the voltage Vc1 exceeds the reference voltage Vf, and switching from the period T12 of the second state to the period T21 of the first state can be performed by setting the comparison result φCO to the high level at timing when the voltage Vc2 exceeds the reference voltage Vf. In this way, the lengths of the periods TP1 and TP2 including the periods T11 and T21 of the first state and the periods T12 and T22 of the second state can be stabilized by being approximately constant.

However, actually, the comparator 22 of the comparison unit 20 has an offset (for example, −ΔVofs). In such a case, as illustrated in FIG. 5 (2), the comparison result φCO is set to the high level at timing when the voltage Vc1 exceeds “the reference voltage Vf−ΔVofs”, which is lower than the reference voltage Vf, and thus switching from a period T11′ of the first state to a period T12′ of the second state is performed. In addition, the comparison result φCO is set to the high level at timing when the voltage Vc2 exceeds “the reference voltage Vf−ΔVofs”, and thus switching from a period T12′ of the second state to the period T21′ of the first state is performed.

In this way, there is a possibility that the lengths of the periods TP1′ and TP2′ including the periods T11′ and T21′ of the first state and the periods T12′ and T22′ of the second state are, for example, shorter than those of the periods TP1 and TP2 of the ideal case. In addition, since the offset (for example, −ΔVofs) of the comparator 22 may easily vary in accordance with a variation in the environments (for example, a variation in the battery voltage or a variation in the ambient temperature), the periods TP1′ and TP2′ tend to be unstable due to variations thereof according to a variation in the environments.

In contrast to this, in the embodiment, by inverting the polarity of the inside of the comparator 22 of the comparison unit 20, the polarity of the offset of the comparator 22 is inverted. In other words, as illustrated in FIG. 5(3), at timing when the voltage Vc1 exceeds “the reference voltage Vf−ΔVofs”, which is lower than the reference voltage Vf, switching from a period T11″ of the first state to a period T12″ of the second state is performed by setting the comparison result φCO to the high level, and, at timing when the voltage Vc2 exceeds “the reference voltage Vf−ΔVofs”, switching from a period T12″ of the second state to a period T21″ of the first state is performed by setting the comparison result φCO to the high level.

Then, the polarity of the inside of the comparator 22 is inverted, and, at timing when the voltage Vc1 exceeds the reference voltage Vf+ΔVofs″, which is higher than the reference voltage Vf, switching from the period T21″ of the first state to a period T22″ of the second state is performed by setting the comparison result φCO to the high level, and, at timing when the voltage Vc2 exceeds the reference voltage Vf+ΔVofs″, switching from the period T22″ of the second state to a period of the first state is performed by setting the comparison result φCO to the high level.

In this way, even when the length of the period TP1″ including the period T11″ of the first state and the period T12″ of the second state is, for example, shorter than that of the period TP1 of the ideal case, the length of the period TP2″ including the period T21″ of the first state and the period T22″ of the second state can be set, for example, to be longer than that of the period TP2 of the ideal case. From this, a variation in the length of the period according to the offset of the comparator 22 can be offset in two periods (in other words, as illustrated in FIG. 5, TP1+TP2≈TP1″+TP2″), and the influence of the offset of the comparator 22 can be reduced.

Here, the oscillation circuit 800 illustrated in FIG. 6A will be considered. As described above, in the oscillation circuit 800 illustrated in FIG. 6A, according to the influence of being incapable of completely discharging the electric charge of the capacitance element, there is a possibility that the frequency of the oscillated periodical pulse varies so as to be unstable, and accordingly, it tends to be difficult for the real-time clock 107 to accurately measure a time during which the IC does not operate.

In contrast to this, according to the embodiment, in the oscillation circuit 1, the switching unit 10 alternately switches between the first state in which the current source CS1 is connected to the capacitance element C1 and the ground electric potential is connected to the capacitance element C2 and the second state in which the current source CS1 is connected to the capacitance element C2 and the ground electric potential is connected to the capacitance element C1 in accordance with a comparison result acquired by the comparison unit 20. The comparison unit 20 compares the voltage charged in the capacitance element C1 and the reference voltage with each other in the first state and compares the voltage charged in the capacitance element C2 and the reference voltage with each other in the second state. The generation unit 30 generates a periodical pulse based on the comparison result acquired by the comparison unit 20. From this, the periodical pulse φDFF2 can be generated by alternately using a time in which the capacitance element C1 is linearly charged by the current source CS1 and a time in which the capacitance element C2 is linearly charged by the current source CS1 in a time-divisional manner, whereby it is difficult to have an influence of being incapable of completely discharging the electric charge of the capacitance element. In addition, since one of the capacitance elements C1 and C2 is discharged during a period in which the other is charged, a period for discharging is sufficiently secured, and accordingly, the electric charge of the capacitance element can be completely discharged. Thus, according to the embodiment, the frequency of the oscillated periodical pulse of the oscillation circuit 1 can be stabilized more than the oscillation circuit 800 illustrated in FIG. 6A, and accordingly, the real-time clock 107 to which the oscillation circuit 1 is applied can accurately measure the time during which the IC does not operate.

Alternately, an oscillation circuit 900 illustrated in FIG. 7A will be considered. As described above, in the oscillation circuit 900 illustrated in FIG. 7A, in order to linearly discharge two reference capacitance elements 905a and 905b while the discharge periods of the two reference capacitance elements 905a and 905b partially overlap each other, two current sources (transistors 808a and 808b) allow currents to continuously flow at all times, and accordingly, the power consumption of the oscillation circuit 900 may easily increase. In addition, the driving capability of the external current source used for supplying the reference voltage Vf901 is much greater than the driving capability of the transistors 906a and 906b, the external current source is understood to supply an extremely large current to the oscillation circuit 900, and accordingly, the power consumption of the oscillation circuit 900 may easily increase in this point of view. Accordingly, there is a possibility that the source power of the battery 107a is depleted, and it tends to be difficult for the real-time clock 107 to accurately measure a time during which the IC does not operate.

In contrast to this, according to the embodiment, in the oscillation circuit 1, one current source CS1 alternately charges the capacitance elements C1 and C2, in other words, the number of current sources used for charging two capacitance elements C1 and C2 can be suppressed to one, and accordingly, the power consumption of the oscillation circuit 1 can be suppressed. In addition, since rapid charging is not performed, an external current source having a high driving capability does not need to be prepared, and an extremely large current does not need to flow in the oscillation circuit 1, whereby the power consumption of the oscillation circuit 1 can be suppressed from this point of view. From this, the source power of the battery 107a can be maintained long, and accordingly, it is easy for the real-time clock 107 to measure a time during which the IC does not operate for a long time.

In addition, according to the embodiment, in the oscillation circuit 1, the differential amplification unit 40 adjusts the bias voltage of the current source CS2 such that the voltage Vf of the reference node Nf becomes the standard reference voltage Vref and supplies the adjusted bias voltage simultaneously to both the current sources CS1 and CS2. In addition, the current source CS2 configures a current mirror circuit of the current source CS1 through the differential amplification unit 40. From this, the capacitance element C1 or C2 can be charged by a constant current Ib1 that is proportional to the bias current Ib2 used for generating the reference voltage Vf, and accordingly, the charging times for the capacitance elements C1 or C2 can be stabilized to be approximately constant.

Alternatively, in the oscillation circuit 800 illustrated in FIG. 6A, the comparator 803 is assumed to have an offset. Accordingly, a reference value that is actually used by the comparator 803 for comparison is shifted from the reference voltage Vf800 by the offset, and accordingly, there is a possibility that the length of the period of the generated periodical pulse φOUT800 is, for example, shorter than that of the period of the ideal case. In addition, since the offset of the comparator 803 may easily vary in accordance with a variation in the environments (for example, a variation in the battery voltage or a variation in the ambient temperature), the period of the periodical pulse φOUT800 tends to vary to be unstable in accordance with a variation in the environment.

Alternatively, in the oscillation circuit 900 illustrated in FIG. 7A, the comparator 903 is assumed to have an offset. Accordingly, a reference value that is actually used by the comparator 903 for comparison is shifted from the reference voltage Vf902 by the offset, and accordingly, there is a possibility that the length of the period of the generated periodical pulse φOUT900 is, for example, shorter than that of the period of the ideal case. In addition, since the offset of the comparator 903 may easily vary in accordance with a variation in the environments (for example, a variation in the battery voltage or a variation in the ambient temperature), the period of the periodical pulse φOUT900 tends to vary to be unstable in accordance with a variation in the environment.

In contrast to this, according to the embodiment, in the oscillation circuit 1, the polarity of the inside of the comparator 22 of the comparison unit 20 is alternately inverted between the first polarity and the second polarity, whereby the polarity of the offset of the comparator 22 is alternately inverted. From this, a variation in the length of the period according to the offset of the comparator 22 can be offset in two periods (in other words, as illustrated in FIG. 5, TP1+TP2≈TP1″+TP2″), and the influence of the offset of the comparator 22 can be reduced. In other words, even when there is a variation in the environments (for example, a variation in the battery voltage or a variation in the ambient temperature), the period of the periodical pulse φDFF2 generated based on the comparison result φCO acquired by the comparator 22 can be stabilized.

In addition, according to the embodiment, in the oscillation circuit 1, the connection unit 21 of the comparison unit 20 connects the capacitance element C1 to the input terminal 22a and connects the reference node Nf to the input terminal 22b in the first polarity and the first state, connects the capacitance element C2 to the input terminal 22a and connects the reference node Nf to the input terminal 22b in the first polarity and the second state, connects the capacitance element C1 to the input terminal 22b and connects the reference node Nf to the input terminal 22a in the second polarity and the first state, and connects the capacitance element C2 to the input terminal 22b and connects the reference node Nf to the input terminal 22a in the second polarity and the second state. Accordingly, in accordance with the switching, which is performed by the switching unit 10, of the state to one of the first state and the second state and the inverting of the polarity of the comparator 22 using the comparison unit 20, a connection destination of the comparator 22 can be appropriately set.

Furthermore, in the embodiment, in the comparator 22 of the oscillation circuit 1, the connection circuit 223 connects the output terminal 221c of the differential amplifier 221 to the input terminal 222b of the comparator 222 and connects the output terminal 221d of the differential amplifier 221 to the input terminal 222a of the comparator 222 in the first polarity, and connects the output terminal 221c of the differential amplifier 221 to the input terminal 222a of the comparator 222 and connects the output terminal 221d of the differential amplifier 221 to the input terminal 222b of the comparator 222 in the second polarity. From this, the comparison unit 20 can invert the polarity of the inside of the comparator 22 between the first polarity and the second polarity.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. An oscillation circuit comprising:
a current source;
a first capacitance element;
a second capacitance element;
a switching unit that switches between a first state in which the current source is connected to the first capacitance element and a ground electric potential is connected to the second capacitance element and a second state in which the current source is connected to the second capacitance element and the ground electric potential is connected to the first capacitance element;
a comparison unit that compares a voltage charged in the first capacitance element and a reference voltage with each other in the first state and compares a voltage charged in the second capacitance element and the reference voltage with each other in the second state; and
a generation unit that generates a periodical pulse based on a comparison result acquired by the comparison unit,
wherein the switching unit alternately switches between the first state and the second state based on the comparison result acquired by the comparison unit.

2. The oscillation circuit according to claim 1, wherein
the switching unit causes the oscillation circuit to perform an operation of the first state and an operation of the second state in a time-divisional manner.

3. The oscillation circuit according to claim 1,
wherein the first capacitance element is connected to the current source through the switching unit, and
the second capacitance element is connected to the current source through the switching unit.

4. The oscillation circuit according to claim 3,
wherein one end of the first capacitance element is connected to the current source through the switching unit and is connected to the comparison unit,
an other end of the first capacitance element is connected to the ground electric potential,
one end of the second capacitance element is connected to the current source through the switching unit and is connected to the comparison unit, and
an other end of the second capacitance element is connected to the ground electric potential.

5. The oscillation circuit according to claim 4,
wherein the first state is a state in which the other end of the first capacitance element and the other end of the second capacitance element are connected to the ground electric potential, the current source is connected to the one end of the first capacitance element, and the ground electric potential is connected to the one end of the second capacitance element, and
the second state is a state in which the other end of the first capacitance element and the other end of the second capacitance element are connected to the ground electric potential, the current source is connected to the one end of the second capacitance element, and the ground electric potential is connected to the one end of the first capacitance element.

6. The oscillation circuit according to claim 5,
wherein the first state is a state in which the first capacitance element is chargeable and the second capacitance element is dischargeable, and
the second state is a state in which the second capacitance element is chargeable and the first capacitance element is dischargeable.

7. The oscillation circuit according to claim 4,
wherein the switching unit includes:
a first switch that connects the one end of the second capacitance element to the ground electric potential;
a second switch that connects the one end of the first capacitance element to the ground electric potential;
an eleventh switch that connects the one end of the first capacitance element to the current source; and
a twelfth switch that connects the one end of the second capacitance element to the current source.

8. The oscillation circuit according to claim 7,
wherein the first switch and the eleventh switch are turned on and off in synchronization with each other,
the second switch and the twelfth switch are turned on and off in synchronization with each other, and
the first and eleventh switches and the second and twelfth switches are exclusively turned on and off.

9. The oscillation circuit according to claim 7,
wherein one end of the first switch is electrically connected to the ground electric potential,
an other end of the first switch is electrically connected to the one end of the second capacitance element,
one end of the second switch is electrically connected to the ground electric potential,
an other end of the second switch is electrically connected to the one end of the first capacitance element,
one end of the eleventh switch is electrically connected to the current source,
an other end of the eleventh switch is electrically connected to the one end of the first capacitance element,
one end of the twelfth switch is electrically connected to the current source, and
an other end of the twelfth switch is electrically connected to the one end of the second capacitance element.

10. The oscillation circuit according to claim 1, further comprising:
a second current source;
a voltage source that is connected to the second current source through a reference node and generates a voltage according to a current; and
a differential amplification unit that adjusts a bias voltage of the second current source such that a voltage of the reference node becomes a standard reference voltage and supplies the adjusted bias voltage to both of the current source and the second current source,
wherein the second current source forms a current mirror circuit of the current source through the differential amplification unit, and
the comparison unit receives the voltage of the reference node as the reference voltage.

11. The oscillation circuit according to claim 1, wherein
the comparison unit switches a comparison operation between a first comparison operation and a second comparison operation for every period including a period in which switching to the first state is performed and a period in which switching to the second state is performed.

12. The oscillation circuit according to claim 11, wherein
the comparison unit includes a comparator, and polarity of an inside of the comparator is inverted between first polarity and second polarity for every period including the period in which switching to the first state is performed and the period in which switching to the second state is performed.

13. The oscillation circuit according to claim 12, further comprising:
a second current source;
a voltage source that is connected to the second current source through a reference node and generates a voltage according to a current; and
a differential amplification unit that adjusts a bias voltage of the second current source such that a voltage of the reference node becomes a standard reference voltage and supplies the adjusted bias voltage to both of the current source and the second current source,
wherein the second current source forms a current mirror circuit of the current source through the differential amplification unit, and
the comparison unit receives the voltage of the reference node as the reference voltage.

14. The oscillation circuit according to claim 13,
wherein the comparator has a first input terminal and a second input terminal,
wherein the comparison unit receives the voltage of the reference node as the reference voltage, and
wherein the comparison unit further includes a connection unit that connects the first capacitance element to the first input terminal and connects the reference node to the second input terminal in the first polarity and the first state, connects the second capacitance element to the first input terminal and connects the reference node to the second input terminal in the first polarity and the second state, connects the first capacitance element to the second input terminal and connects the reference node to the first input terminal in the second polarity and the first state, and connects the second capacitance element to the second input terminal and connects the reference node to the first input terminal in the second polarity and the second state.

15. The oscillation circuit according to claim 14,
wherein the connection unit includes:
a third switch that connects the reference node to the first input terminal of the comparator;
a fourth switch that connects the reference node to the second input terminal of the comparator;
a fifth switch that connects one end of the first capacitance element to the first input terminal of the comparator;
a sixth switch that connects one end of the first capacitance element to the second input terminal of the comparator;
a seventh switch that connects one end of the second capacitance element to the first input terminal of the comparator; and
an eighth switch that connects one end of the second capacitance element to the second input terminal of the comparator.

16. The oscillation circuit according to claim 15,
wherein the connection unit turns on the fourth switch and the fifth switch and turns off the third switch, the sixth switch, the seventh switch, and the eighth switch in the first polarity and the first state, turns on the fourth switch and the seventh switch and turns off the third switch, the fifth switch, the sixth switch, and the eighth switch in the first polarity and the second state, turns on the third switch and the sixth switch and turns off the fourth switch, the fifth switch, the seventh switch, and the eighth switch in the second polarity and the first state, and turns on the third switch and the eighth switch and turns off the fourth switch, the fifth switch, the sixth switch, and the seventh switch in the second polarity and the second state.

17. The oscillation circuit according to claim 14,
wherein the comparator outputs a signal of a low level as a comparison result when a level of a signal of the second input terminal is lower than a level of a signal of the first input terminal and outputs a signal of a high level as a comparison result when the level of the signal of the second input terminal is lower than the level of the signal of the first input terminal in the first polarity, and
the comparator outputs a signal of the low level as a comparison result when the level of the signal of the first input terminal is lower than the level of the signal of the second input terminal and outputs a signal of the high level as a comparison result when the level of the signal of the second input terminal is lower than the level of the signal of the first input terminal in the second polarity.

18. The oscillation circuit according to claim 14,
wherein the comparator includes:
a differential amplifier that has the first input terminal, the second input terminal, a first output terminal, and a second output terminal;
a comparator that has a third input terminal, a fourth input terminal, and a third output terminal; and
a connection circuit that connects the first output terminal to the fourth input terminal and connects the second output terminal to the third input terminal in the first polarity, and connects the first output terminal to the third input terminal and connects the second output terminal to the fourth input terminal in the second polarity.

19. A real-time clock comprising:
a battery;
the oscillation circuit according to claim 1 which generates a periodical pulse using power supplied from the battery; and
an adjustment circuit that generates a clock signal by adjusting the generated periodical pulse.

20. An information processing device comprising:
a main power supply;
an IC; and
a real-time clock according to claim 19 which measures a time during which the IC does not operate while the main power supply is turned off.
